(19) United States
(12) Patent Application Publication
(10) Pub. No.: US 2007/0079201 A1
(43) Pub. Date: Apr. 5, 2007

(54) Power-saving apparatus according to the operating mode of an embedded memory

(75) Inventor: Chih-Hao Chung, Taipei (TW)

Correspondence Address: BIRCH STEWART KOLASCH & BIRCH, PO BOX 747, FALLS CHURCH, VA, 22040-0747, US

(73) Assignee: Ali Corporation

(21) Appl. No.: 11/507,581

(22) Filed: Aug. 22, 2006

(30) Foreign Application Priority Data
Sep. 9, 2005 (TW) 94131101

(51) Int. Cl. G01R 31/28

(52) U.S. Cl. 714/733

(57) ABSTRACT

A power-saving apparatus according to the operating mode of an embedded memory is provided for solving the problems of the prior art, such as the embedded memory only being able to reduce power consumption in a normal operating mode and being unable to save power in other operating modes. The present invention divides the control circuit of the embedded memory unit into an embedded memory, a self-testing circuit and a scanning other-circuit circuit according to the operating mode. Furthermore, the present invention depends on the operating mode to determine whether the embedded memory is operating or not to reduce power consumption.

### BACKGROUND OF THE INVENTION

1. Field of the Invention

The present invention relates to a power-saving apparatus according to the operating mode of an embedded memory. In particular, an apparatus that makes an embedded memory enter a corresponding power-saving mode according to the operating mode of the embedded memory.

2. Description of the Related Art

Application specific integrated circuits (ASICs) are applied to a variety of electronic elements and including a memory system. There are two methods for testing the embedded memory in ASICs. The first method uses an external testing device to connect with external pins of the ASICs and generates a variety of testing patterns to test the embedded memory. If the data read from the memory system is different from the data written to the memory system, the memory system is adjusted to a defect system by the testing devices. In order for the external testing devices to test the embedded memory, additional pins are necessary for connecting to the testing devices. Therefore, the loading of the circuit and the number of pins increases.

The second method includes a built-in self-testing unit (BIST) in the ASIC for testing the embedded memory. When the ASIC receives power or an external triggering signal, the built-in self-testing unit is started, and outputs a testing pattern to test the embedded memory and compares the testing pattern with the data read from the embedded memory. The built-in self-testing unit assigns a pin to indicate whether the embedded memory is defective or not. This method requires fewer pins for testing and can test a lot of memory modules at the same time. Therefore, the testing time is reduced.

A built-in self-testing unit (BIST) or a circuit thereof embedded in the ASIC was disclosed in U.S. Pat. No. 6,226,211 “Merged memory-logic semiconductor device having a built-in self test circuit.” It disclosed a technology of merging a memory and a logic circuit in a single semiconductor device. Another U.S. Pat. No. 6,226,764B1 “Integrated circuit memory devices including internal stress voltage generating circuits and methods for built-in self test”, disclosed a built-in self test circuit and method for the integrated circuit memory devices.

A further U.S. Pat. No. 6,668,347B1 “Built-in self-testing for embedded memory”, discloses a built-in self-testing circuit for embedded memory.

The conventional embedded memory only considers a power-saving method for a normal operating mode. The control signal stops the operation of the embedded memory in the normal operating mode to save power consumption. However, as power consumption during the testing becomes more and more important, the conventional method cannot reduce power consumption of the embedded memory according to the different operation modes (normal operating mode, scanning testing mode and memory self-test mode).

### SUMMARY OF THE INVENTION

One particular aspect of the present invention is to provide a power-saving apparatus according to the operating mode of an embedded memory to reduce power consumption of embedded memory according to different operation modes (normal operating mode, scanning testing mode and memory self-test mode).

The power-saving apparatus according to the operating mode of an embedded memory includes a memory enable unit, a memory clock control unit, a self-testing circuit control unit and a scanning other-circuit control unit. The memory enable unit receives an external control signal and a selection signal of a scanning mode for outputting an enable signal to a memory enable port of an embedded memory unit. The memory clock control unit receives a clock signal and an inverse-selection signal of the scanning mode for outputting a memory clock signal to the memory of the embedded memory unit. The self-testing circuit control unit receives a self-testing selection signal, the selection signal of the scanning mode, a control signal of the scanning mode and the clock signal for outputting a self-testing circuit clock signal to a memory self-testing circuit of the embedded memory unit. The scanning other-circuit control unit receives the clock signal and the selection signal of the scanning mode for outputting an other-circuit clock signal to a scanning other-circuit circuit of the embedded memory unit.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide further understanding of the invention. A brief introduction of the drawings is as follows:

FIG. 1A is a schematic diagram of a power-saving apparatus according to the operating mode of an embedded memory of the present invention;

FIG. 1B is a schematic diagram of a self-testing circuit control unit;

FIG. 1C is a schematic diagram of a clock gate unit;

FIG. 2 is a schematic diagram of a single-port power-saving structure according to the operating mode of an embedded memory of the present invention; and

FIG. 3 is a schematic diagram of a dual-port power-saving structure according to the operating mode of an embedded memory of the present invention.

### DETAILED DESCRIPTION OF THE PREFERRED EMBODIMENTS

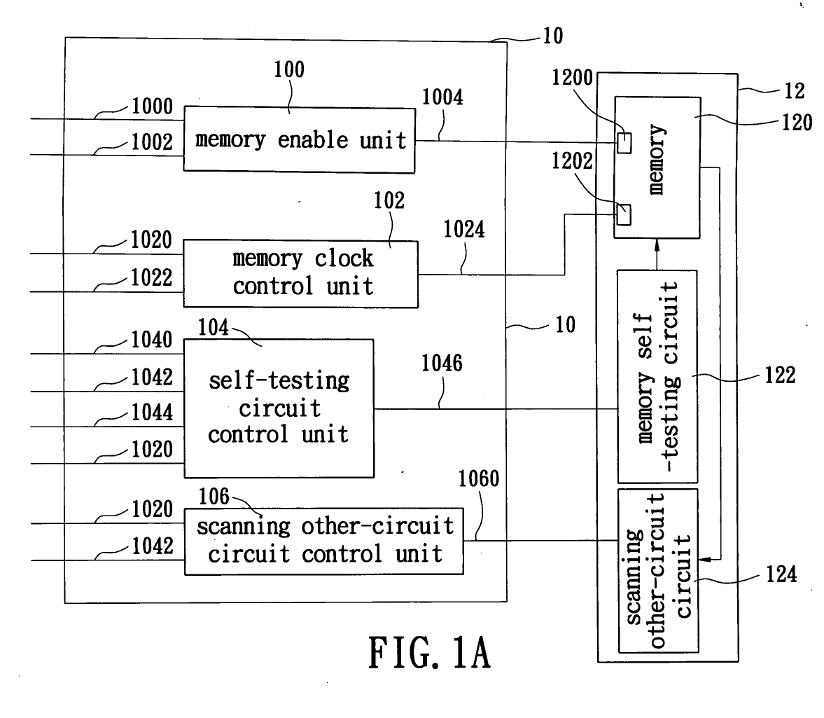

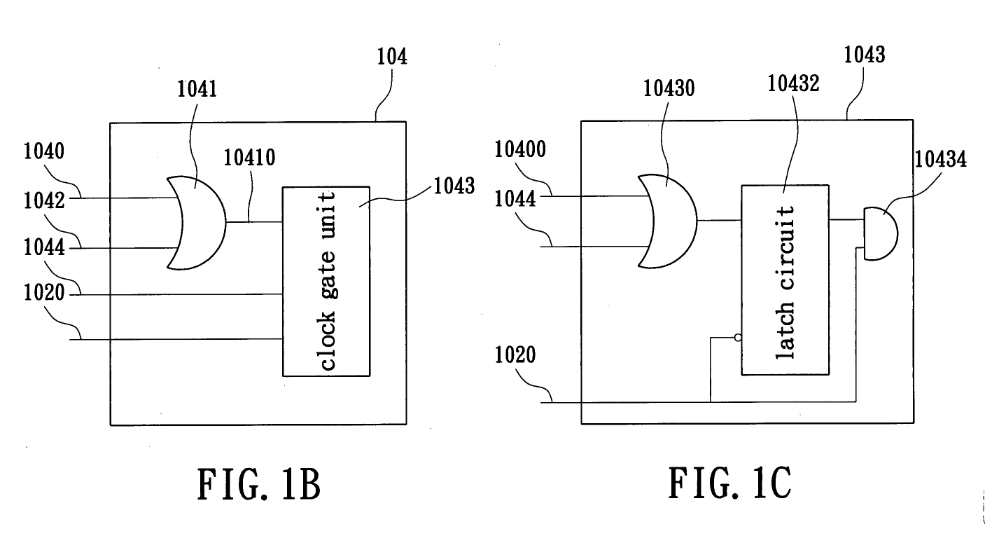

Please refer to FIG. 1, which shows a schematic diagram of a power-saving apparatus according to the operating mode of an embedded memory of the present invention. The power-saving apparatus according to the operating mode of an embedded memory 10 includes a memory enable unit 100, a memory clock control unit 102, a self-testing circuit control unit 104 and a scanning other-circuit control unit 106. The memory enable unit 100 receives an external control signal 1000 and a selection signal of a scanning mode 1002 for outputting an enable signal 1004 to an enable input port 1200 of a memory 120 of an embedded memory unit 12. The memory enable unit 100 is an OR gate. The embedded memory unit 12 includes a memory 120, a memory self-testing circuit 122 and a scanning other-circuit circuit 124. The memory self-testing circuit 122 is electrically connected with the memory 120 and the scanning other-circuit circuit 124. The memory 12 can be an SRAM or a DRAM.

The memory clock control unit 102 receives a clock signal 1020 and an inverse-selection signal of the scanning mode 1022 for outputting a memory clock signal 1024 to a clock input port 1202 of the memory 120 of the embedded memory unit 12. The memory clock control unit 102 is an AND gate. The self-testing circuit control unit 104 receives a self-testing selection signal 1040, a selection signal of the scanning mode 1042, a control signal of a scanning mode 1044 and the clock signal 1020 for outputting a self-testing circuit clock signal 1046 to a memory self-testing circuit 122 of the embedded memory unit 12. The scanning other-circuit control unit 106 receives the clock signal 1020 and the selection signal of the scanning mode 1042 for outputting an other-circuit clock signal 1060 to the scanning other-circuit circuit 124 of the embedded memory unit 12. The scanning other-circuit control unit 106 is an AND gate.

Please refer to FIG. 1B, which shows a schematic diagram of the self-testing circuit control unit. The self-testing circuit control unit 104 includes an OR gate 1041 and a clock gate unit 1043. The OR gate 1041 receives the self-testing selection signal 1040 and the selection signal of the scanning mode 1042. The clock gate unit 1043 receives an output control signal generated from the OR gate 1042, the control signal of the scanning mode 1044 and the clock signal 1020 for outputting the self-testing circuit clock signal to the memory self-testing circuit 122 of the embedded memory unit 12. Please refer to FIG. 1C, which shows a schematic diagram of a clock gate unit. The clock gate unit 1043 further includes an OR gate 10430, a latch circuit 10432 and an AND gate 10434. The OR gate 10430 is used for receiving the output control signal 10410 of the OR gate 1041 and the control signal of the scanning mode 1044. A data input port of the latch circuit 10432 is electrically connected with an output port of the OR gate 10430 and receives the clock signal 1020 via an enable input port. The latch circuit 10432 is composed of a D-type circuit and is triggered by low levels. The AND gate 10434 is electrically connected with an output port of the latch circuit 10432 and receives the clock signal 1020.

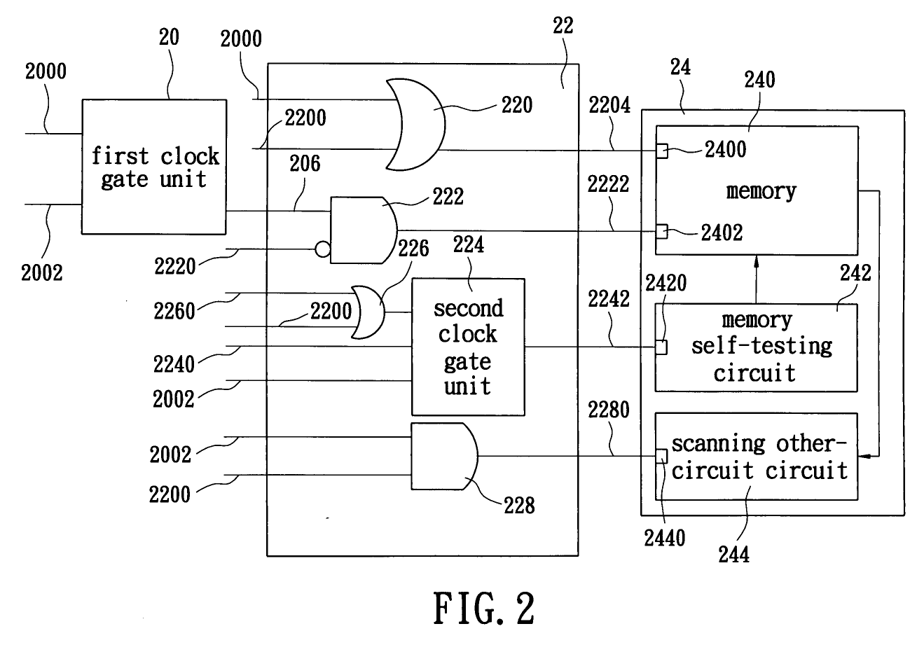

Please refer to FIG. 2, which shows a schematic diagram of a single-port power-saving structure according to the operating mode of an embedded memory of the present invention. The single-port power-saving structure according to the operating mode of an embedded memory includes a first clock gate unit 20, a power-saving control circuit 22 and an embedded memory unit 24. The first clock gate unit 20 receives a control signal 2000 and a clock signal 2002. The first clock gate unit 20 further includes an OR gate, a latch circuit, and an AND gate. The OR gate receives the control signal 2000 and the clock signal 2002. A data input port of the latch circuit is electrically connected with an output port of the OR gate. The latch circuit is composed of a D-type circuit. The AND gate is electrically connected with an output port of the latch circuit and a clock input port. The inner circuit of the first clock gate unit 20 is the same as FIG. 1C.

The power-saving control circuit 22 is electrically connected with the first clock gate unit 20 for receiving an output signal 206 outputted from the first clock gate unit 20. The embedded memory unit 24 is electrically connected with the power-saving control circuit 22 for receiving a plurality of control signals outputted from the power-saving control circuit 22 to make the embedded memory unit 24 enter one of the power-saving modes according to the control signals. The embedded memory unit 24 further includes a memory 240, a memory self-testing circuit 242 and a scanning other-circuit circuit 244. The memory self-testing circuit 242 is electrically connected with the memory 240 and the scanning other-circuit circuit 244. The memory 240 is an SRAM or a DRAM. The power-saving modes include a normal operating mode, a scanning mode and a self-testing mode.

The power-saving control circuit 22 further includes a first OR gate 220 and a first AND gate 222, a second clock gate unit 224, a second OR gate 226 and a second AND gate 228. The first OR gate 220 receives the control signal 2000 and a selection signal of a scanning mode 2200 and outputs an enable signal 2204 to an enable an input port 2400 of the memory 240 of the embedded memory unit 24. The first AND gate 222 receives the output signal 206 of the first clock gate unit 20 and an inverse-selection signal of the scanning mode for outputting a system clock signal 2222 to a memory clock input port 2402 of the memory 240 of the embedded memory unit 24.

A second clock gate unit 224 receives an output control signal of the second OR gate 226, a scanning mode control signal 2240 and the clock signal 2002 for outputting a self-testing signal to a self-testing clock input port 2420 of the memory self-testing circuit 242 of the embedded memory unit 24. The second clock gate unit 224 further includes an OR gate, a latch circuit, and an AND gate. The OR gate receives a self-testing selection signal and the selection signal of the scanning mode. A data input port of the latch circuit is electrically connected with an output port of the OR gate. The AND gate is electrically connected with an output port of the latch circuit and a clock input port. The inner circuit of the second clock gate unit 224 is the same as the ones in FIG. 1C.

The second OR gate 226 receives the self-testing selection signal 2260 and the selection signal of the scanning mode 2200 for outputting the output control signal to the second clock gate unit 224. A second AND gate 228 receives the clock signal 2002 and the selection signal of the scanning mode 2200 for outputting a clock control signal 2280 to a scanning other-circuit input port 2440 of the scanning other-circuit circuit of the embedded memory unit 24.

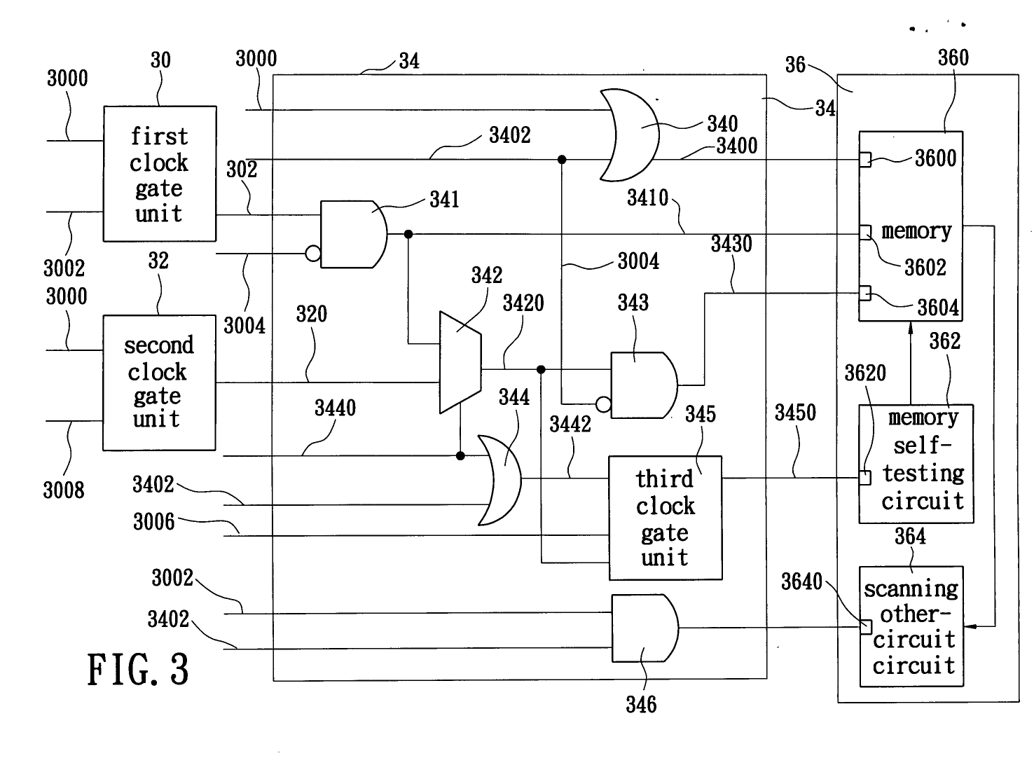

Please refer to FIG. 3, which shows a schematic diagram of a dual-port power-saving structure according to the operating mode of an embedded memory of the present invention. The dual-port power-saving structure according to the operating mode of an embedded memory includes a first clock gate unit 30, a second clock gate unit 32, a power-saving control circuit 34 and an embedded memory unit 36. The first clock gate unit 30 receives a control signal 3000 and a first clock signal 3002. The second clock gate unit 32 receives the control signal 3000 and a second clock signal 3008. The first clock gate unit 30 and the second clock gate unit 32 further include an OR gate, a latch circuit and an AND gate. The OR gate receives the control signal 3000 and the first clock signal 3002 and the second clock signal 3008. A data input port of the latch circuit is electrically connected with an output port of the OR gate. The AND gate is electrically connected with an output port of the latch circuit and a clock input port. The latch circuit is composed of a D-type circuit. The inner circuit of the first clock gate unit 30 and the second clock gate unit 32 are the same as the ones in FIG. 1C.

The power-saving control circuit 34 is electrically connected with the first clock gate unit 30 and the second clock gate unit 32 for receiving a first clock signal 302 outputted from the first clock gate unit 30 and a second clock signal 320 of the second clock gate unit 3. The power-saving control circuit 34 further includes a first OR gate 340, a first AND gate 341, a multiplexer 342, a second AND gate 343, a second OR gate 344, a third clock gate unit 345 and a second AND gate 346. The first OR gate 340 receives the control signal 3000 and a selection signal of a scanning mode 3402 and outputs an enable signal 360 to an enable input port 3600 of the memory 360 of the embedded memory unit 36. The first AND gate 341 receives the first clock signal 302 outputted from the first clock gate unit 30 and an inverse-selection signal of the scanning mode 3004 for outputting a first system clock signal 3410 to a first clock input port 3602 of the memory 360 of the embedded memory unit 36.

The multiplexer 342 receives the first system clock signal 3410 outputted from the first AND gate 341 and the second clock signal 320 outputted from the second clock gate unit 32. A second AND gate 343 receives the output signal 3420 outputted from the multiplexer 342 and the inverse-selection signal of the scanning mode 3004 for outputting a second system clock signal 3430 to a second clock signal input port 3604 of the memory 36 of the embedded memory unit 36. The second OR gate 344 receives the self-testing selection signal 3440 and the selection signal of the scanning mode 3402 for enabling the operation of the multiplexer 342. The self-testing selection signal 3440 is electrically connected with an enable input port of the multiplexer 342. The third clock gate unit 345 receives an output control signal 3442 of the second OR gate 344, a control signal of the scanning mode 3006 and the output signal 3420 of the multiplexer 342 for outputting a self-testing signal 3450 to a self-testing clock input port 3620 of a memory self-testing circuit 362 of the embedded memory unit 36.

The second AND gate 346 receives the first clock signal 3002 and the selection signal of the scanning mode 3402. An embedded memory unit 36 is electrically connected with the power-saving control circuit 34 for receiving a plurality of control signals outputted from the power-saving control circuit 34 to make the embedded memory unit 36 enter one of the power-saving modes according to the control signals. The power-saving modes include a normal operating mode, a scanning mode and a self-testing mode. The third clock gate unit 345 further includes an OR gate, a latch circuit, and an AND gate. The OR gate receives the control signal, a first clock, and a second clock. A data input port of the latch circuit is electrically connected with an output port of the OR gate. The AND gate is electrically connected with an output port of the latch circuit and a clock input port.

When the dual-port power-saving structure according to the operating mode of an embedded memory executes a self-testing mode, it utilizes the multiplexer to make the signals synchronize due to the signals outputted from the two clock gate units (the first clock gate unit and the second clock gate unit) are asynchronous. When the dual-port power-saving structure according to the operating mode of an embedded memory executes a normal operating mode, it needs asynchronous signals. Therefore, the multiplexer is used for selecting the self-testing mode or the normal operating mode.

However, the embedded memory unit needs to reduce power consumption in the normal operating mode, it also needs to reduce power consumption in both the memory self-testing mode and the scanning testing mode. The present invention divides the control circuit of the embedded memory unit into an embedded memory, a self-testing circuit, and a scanning other-circuit circuit according to the operating mode. The present invention depends on the operating mode to determine whether the embedded memory is operating or not to reduce power consumption.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A power-saving apparatus according to the operating mode of an embedded memory, comprising:
a memory enable unit, receiving an external control signal and a selection signal of a scanning mode, and outputting an enable signal to an enable port of an embedded memory unit;
a memory clock control unit, receiving a clock signal and an inverse-selection signal of the scanning mode and outputting a memory clock signal to a clock input port of a memory of the embedded memory unit;
a self-testing circuit control unit, receiving a self-testing selection signal, a selection signal of the scanning mode, a control signal of the scanning mode and the clock signal and outputting a self-testing circuit clock signal to a memory self-testing circuit of the embedded memory unit; and
a scanning other-circuit control unit, receiving the clock signal and the selection signal of the scanning mode and outputting an other-circuit clock signal to a scanning other-circuit circuit of the embedded memory unit.

2. The power-saving apparatus according to the operating mode of an embedded memory as claimed in claim 1, wherein the embedded memory unit comprises a memory, a memory self-testing circuit and a scanning other-circuit circuit.

3. The power-saving apparatus according to the operating mode of an embedded memory as claimed in claim 1, wherein the memory self-testing circuit is electrically connected with the memory and the scanning other-circuit circuit.

4. The power-saving apparatus according to the operating mode of an embedded memory as claimed in claim 1, wherein the memory is an SRAM or a DRAM.

5. The power-saving apparatus according to the operating mode of an embedded memory as claimed in claim 1, wherein the memory enable unit is an OR gate.

6. The power-saving apparatus according to the operating mode of an embedded memory as claimed in claim 1, wherein the memory clock control unit is an AND gate.

7. The power-saving apparatus according to the operating mode of an embedded memory as claimed in claim 1, wherein the self-testing circuit control unit comprises an OR gate and a clock gate unit.

8. The power-saving apparatus according to the operating mode of an embedded memory as claimed in claim 7, wherein the clock gate unit further comprises:
an OR gate, receiving a self-testing selection signal and a selection signal of the scanning mode;
a latch circuit, wherein a data input port of the latch circuit is electrically connected with an output port of the OR gate; and
an AND gate, electrically connected with an output port of the latch circuit and a clock input port.

9. The power-saving apparatus according to the operating mode of an embedded memory as claimed in claim 8, wherein the latch circuit is composed of a D-type circuit.

10. The power-saving apparatus according to the operating mode of an embedded memory as claimed in claim 1, wherein the scanning other-circuit control unit is an AND gate.

11. A single-port power-saving structure according to the operating mode of an embedded memory, comprising:
a first clock gate unit, receiving a control signal and a clock signal;
a power-saving control circuit, electrically connected with the first clock gate unit for receiving a clock signal outputted from the first clock gate unit; and
an embedded memory unit, electrically connected with the power-saving control circuit for receiving a plurality of control signals outputted from the power-saving control circuit to make the embedded memory unit enter one of the power-saving modes according to the control signals.

12. The single-port power-saving structure according to the operating mode of an embedded memory as claimed in claim 11, wherein the first clock gate unit further comprises:
an OR gate, receiving the control signal and the clock signal;
a latch circuit, wherein a data input port of the latch circuit is electrically connected with an output port of the OR gate; and
an AND gate, electrically connected with an output port of the latch circuit and a clock input port.

13. The single-port power-saving structure according to the operating mode of an embedded memory as claimed in claim 12, wherein the latch circuit is composed of a D-type circuit.

14. The single-port power-saving structure according to the operating mode of an embedded memory as claimed in claim 11, wherein the power-saving control circuit further comprises:
a first OR gate, receiving the control signal and a selection signal of a scanning mode, and outputting an enable signal to an enable input port of the embedded memory unit;
a first AND gate, receiving the output signal of the first clock gate unit and an inverse-selection signal of the scanning mode and outputting a system clock signal to a memory of the embedded memory unit;
a second clock gate unit, receiving an output control signal of the first OR gate, a scanning mode control signal and the clock signal and outputting a self-testing signal to a memory self-testing circuit of the embedded memory unit; and
a second AND gate, receiving the clock signal and the selection signal of the scanning mode.

15. The single-port power-saving structure according to the operating mode of an embedded memory as claimed in claim 14, wherein the second clock gate unit further comprises:
an OR gate, receiving a self-testing selection signal and a selection signal of the scanning mode;
a latch circuit, wherein a data input port of the latch circuit is electrically connected with an output port of the OR gate; and
an AND gate, electrically connected with an output port of the latch circuit and a clock input port.

16. The single-port power-saving structure according to the operating mode of an embedded memory as claimed in claim 15, wherein the latch circuit is composed of a D-type circuit.

17. The single-port power-saving structure according to the operating mode of an embedded memory as claimed in claim 14, wherein the output port of the second AND gate outputs an other-circuit clock signal to a scanning other-circuit circuit of the embedded memory unit.

18. The single-port power-saving structure according to the operating mode of an embedded memory as claimed in claim 14, wherein the embedded memory unit comprises a memory, a memory self-testing circuit and a scanning other-circuit circuit.

19. The single-port power-saving structure according to the operating mode of an embedded memory as claimed in claim 18, wherein the memory self-testing circuit is electrically connected with the memory and the scanning other-circuit circuit.

20. The single-port power-saving structure according to the operating mode of an embedded memory as claimed in claim 18, wherein the memory is an SRAM or a DRAM.

21. The single-port power-saving structure according to the operating mode of an embedded memory as claimed in claim 11, wherein the power-saving mode comprises a normal operating mode, a scanning mode and a self-testing mode.

22. A dual-port power-saving structure according to the operating mode of an embedded memory, comprising:
a first clock gate unit, receiving a control signal and a clock signal;
a second clock gate unit, receiving the control signal and the clock signal;
a power-saving control circuit, electrically connected with the first clock gate unit and the second clock gate unit for receiving a first clock signal and a second clock signal outputted from the first clock gate unit and the second clock gate unit; and
an embedded memory unit, electrically connected with the power-saving control circuit for receiving a plurality of control signals outputted from the power-saving control circuit to make the embedded memory unit enter one of the power-saving modes according to the control signals.

23. The dual-port power-saving structure according to the operating mode of an embedded memory as claimed in claim 22, wherein the first clock gate unit and the second clock gate unit further comprises:
an OR gate, receiving the control signal, a first clock signal and a second clock signal;
a latch circuit, wherein a data input port of the latch circuit is electrically connected with an output port of the OR gate; and
an AND gate, electrically connected with an output port of the latch circuit and a clock input port.

24. The dual-port power-saving structure according to the operating mode of an embedded memory as claimed in claim 23, wherein the latch circuit is composed of a D-type circuit.

25. The dual-port power-saving structure according to the operating mode of an embedded memory as claimed in claim 23, wherein the power-saving control circuit further comprises:
a first OR gate, receiving the control signal and a selection signal of a scanning mode, and outputting an enable signal to an enable input port of the embedded memory unit;
a first AND gate, receiving the output signal of the first clock gate unit and an inverse-selection signal of the scanning mode, and outputting a first system clock signal to a first system clock signal input port of a memory of the embedded memory unit;
a multiplexer, receiving the output control signal outputted from the first AND gate and the output signal outputted from the second clock gate unit;
a second AND gate, receiving the output signal outputted from the multiplexer and an inverse-selection signal of the scanning mode, and outputting a second system clock signal to a second clock signal input port of the memory of the embedded memory unit;
a second OR gate, receiving the self-testing selection signal and the selection signal of the scanning mode, wherein the self-testing selection signal is electrically connected with an enable input port of the multiplexer for enabling the operation of the multiplexer;
a third clock gate unit, receiving an output control signal of the second OR gate, a control signal of the scanning mode and the output signal of the multiplexer, and outputting a self-testing signal to a memory self-testing circuit of the embedded memory unit; and
a second AND gate, receiving the first clock signal and the selection signal of the scanning mode.

26. The dual-port power-saving structure according to the operating mode of an embedded memory as claimed in claim 22, wherein the third clock gate unit further comprises:
an OR gate, receiving the control signal, a first clock and a second clock;
a latch circuit, wherein a data input port of the latch circuit is electrically connected with an output port of the OR gate; and
an AND gate, electrically connected with an output port of the latch circuit and a clock input port.

27. The dual-port power-saving structure according to the operating mode of an embedded memory as claimed in claim 26, wherein the latch circuit is composed of a D-type circuit.

28. The dual-port power-saving structure according to the operating mode of an embedded memory as claimed in claim 22, wherein the embedded memory unit comprises a memory, a memory self-testing circuit and a scanning other-circuit circuit.

29. The dual-port power-saving structure according to the operating mode of an embedded memory as claimed in claim 28, wherein the memory self-testing circuit is electrically connected with the memory and the scanning other-circuit circuit.

30. The dual-port power-saving structure according to the operating mode of an embedded memory as claimed in claim 28, wherein the memory is an SRAM or DRAM.

31. The dual-port power-saving structure according to the operating mode of an embedded memory as claimed in claim 22, wherein the power-saving mode comprises a normal operating mode, a scanning mode, and a self-testing mode.
